(19) United States
(12) Patent Application Publication
(10) Pub. No.: US 2024/0143859 A1
(43) Pub. Date: May 2, 2024

(54) HOISTING PATH PLANNING MODEL CONSTRUCTION METHOD, HOISTING PATH PLANNING METHOD AND CRANE

(71) Applicant: ZHEJIANG SANY EQUIPMENT CO., LTD., Huzhou (CN)

(72) Inventors: Jun XIE, Huzhou (CN); Xiaobin YU, Huzhou (CN); Qiong WU, Huzhou (CN)

(73) Assignee: ZHEJIANG SANY EQUIPMENT CO., LTD., Huzhou (CN)

(21) Appl. No.: 18/409,461

(22) Filed: Jan. 10, 2024

Related U.S. Application Data
(63) Continuation of application No. PCT/CN2023/100942, filed on Jun. 19, 2023.

(30) Foreign Application Priority Data
Jul. 29, 2022 (CN) 202210908341.3

(51) Int. Cl. G06F 30/17; B66C 13/48

(52) U.S. Cl. CPC G06F 30/17; B66C 13/48

(57) ABSTRACT

Disclosed are a hoisting path planning model construction method, a hoisting path planning method and a crane. The hoisting path planning model construction method includes: building a crane model; constructing a hoisting system configuration space model based on a current operation scenario and the crane model, and the hoisting system configuration space model includes upper vehicle body data of a crane and lower vehicle body data of the crane; aiming at the hoisting system configuration space model and the upper vehicle body data, generating upper vehicle body raster graphic data of the crane; and aiming at the hoisting system configuration space model and the lower vehicle body data, generating lower vehicle body raster graphic data of the crane; and using an A-star algorithm and combining the upper vehicle body raster graphic data and the lower vehicle body raster graphic data to construct a hoisting path planning model.

### CROSS-REFERENCE TO RELATED APPLICATIONS

This application is a continuation application of International Application No. PCT/CN2023/100942, filed on Jun. 19, 2023, which claims priority to Chinese Patent Application No. 202210908341.3, filed on Jul. 29, 2022. The disclosures of the above-mentioned applications are incorporated herein by reference in their entireties.

### TECHNICAL FIELD

The present application relates to the technical field of path planning, and in particular to a hoisting path planning model construction method, a hoisting path planning method and a crane.

### BACKGROUND

With the complexity of hoisting construction sites and the requirements for the safety and accuracy of hoisting operations, hoisting operations have become more difficult, in addition to the crane driver, a hoisting work often requires one or more auxiliary personnel; meanwhile, the quality of the hoisting operations are also extremely dependent on the driver's level. In recent years, with the development and application of technologies such as digital twins and intelligent construction sites, hoisting path planning has gained certain practical value.

At present, most hoisting path planning relies on a huge amount of hoisting system data, thus resulting in relatively low efficiency in path search.

### SUMMARY

The present application provides a hoisting path planning model construction method, a hoisting path planning method and a crane to solve the defect of low efficiency of hoisting path planning in the existing technology, and realize that reducing the data volume during path search and improving path planning efficiency by dividing the hoisting path into the upper vehicle body path planning and the lower vehicle body path planning.

The present application provides a hoisting path planning model construction method, including:

building a crane model;

constructing a hoisting system configuration space model based on a current operation scenario and the crane model, and the hoisting system configuration space model includes upper vehicle body data of a crane and lower vehicle body data of the crane;

aiming at the hoisting system configuration space model and the upper vehicle body data, generating upper vehicle body raster graphic data of the crane; aiming at the hoisting system configuration space model and the lower vehicle body data, generating lower vehicle body raster graphic data of the crane; and

using an A-star algorithm and combining the upper vehicle body raster graphic data and the lower vehicle body raster graphic data to construct a hoisting path planning model.

According to a hoisting path planning model construction method provided by the present application, the upper vehicle body data includes: a main arm luffing angle, an upper vehicle body rotation angle and a hook lifting length;

the aiming at the hoisting system configuration space model and the upper vehicle body data, generating the upper vehicle body raster graphic data of the crane includes:

determining the hook lifting length;

dividing the hook lifting length into a preset number of lifting intervals; and

aiming at an endpoint of each lifting intervals, performing a traversal search within the hoisting system configuration space model based on the main arm luffing angle and the upper vehicle body rotation angle, calculating upper vehicle body collision information, and generating the upper vehicle body raster graphic data of the crane.

According to a hoisting path planning model construction method provided by the present application, the lower vehicle body data includes walking parameters and steering parameters;

the aiming at the hoisting system configuration space model and the lower vehicle body data, generating the lower vehicle body raster graphic data of the crane includes:

scanning and traversing within the hoisting system configuration space model based on the walking parameters and the steering parameters to obtain lower vehicle body collision information; and

generating the lower vehicle body raster graphic data of the crane according to the lower vehicle body collision information.

According to a hoisting path planning model construction method provided by the present application, the using the A-star algorithm and combining the upper vehicle body raster graphic data and the lower vehicle body raster graphic data to construct the hoisting path planning model includes:

using the A-star algorithm, performing a path planning on the upper vehicle body raster graphic data and the lower vehicle body raster graphic data respectively to obtain an upper vehicle body path planning model and a lower vehicle body path planning model; and

combining the upper vehicle body path planning model and the lower vehicle body path planning model, and constructing the hoisting path planning model.

The present application further provides a hoisting path planning method, including:

determining a starting point of a hoisting path and an end point of the hoisting path;
and

inputting coordinates of the starting point and coordinates of the end point into a hoisting path planning model, outputting a hoisting planning path as an optimal hoisting path, and the hoisting path planning model is obtained according to the hoisting path planning model construction method described in any one of the above.

According to the hoisting path planning method provided by the present application, after the outputting the hoisting planning path, further including:

aiming at the upper vehicle body raster graphic data and the lower vehicle body raster graphic data respectively, and starting to search for an upper vehicle body raster graphic data node and a lower vehicle body raster graphic data node from the starting point;

aiming at each of the upper vehicle body raster graphic data node and the lower vehicle body raster graphic data node, and determining a departed cost and a predicted cost; and

marking the departed cost and the predicted cost in an open list, searching for a node with a smallest total cost in the open list, and using the node with the smallest total cost as a new starting point to start search until the end point is reached.

According to the hoisting path planning method provided by the present application, after the outputting the hoisting planning path, further including:

converting the hoisting planning path into an action sequence of the crane based on the hoisting system configuration space model; and

generating a crane control instruction based on the action sequence.

The present application further provides a hoisting path planning model construction device, including:

a simulation module configured to build a crane model;

a configuration space module configured to construct a hoisting system configuration space model based on a current operation scenario and the crane model, and the hoisting system configuration space model includes upper vehicle body data of a crane and lower vehicle body data of the crane;

a grouping processing module configured to aim at the hoisting system configuration space model and the upper vehicle body data, generate upper vehicle body raster graphic data of the crane; and configured to aim at the hoisting system configuration space model and the lower vehicle body data, generate lower vehicle body raster graphic data of the crane; and

a construction module configured to use an A-star algorithm and combine the upper vehicle body raster graphic data and the lower vehicle body raster graphic data to construct a hoisting path planning model.

The present application further provides a hoisting path planning device, including:

a determination module configured to determine a starting point of a hoisting path and an end point of the hoisting path; and

a planning module configured to input the starting point and the end point into a hoisting path planning model and output a hoisting planning path, and the hoisting path planning model is obtained according to the hoisting path planning model construction method described in any of the above.

The present application further provides a crane, the crane is configured to execute the hoisting path planning method described in any of the above.

The present application further provides an electronic device, including a memory, a processor and a computer program stored in the memory and executable on the processor, and any one of the hoisting path planning model construction methods described above is implemented when the processor executes the program.

The present application further provides a non-transitory computer-readable storage medium on which a computer program is stored, and the hoisting path planning model construction method as described in any one of the above is implemented when the computer program is executed by a processor,

The present application further provides a computer program product, including a computer program, and the hoisting path planning model construction method as described above is implemented when the computer program is executed by a processor.

The present application provides a hoisting path planning model construction method, a hoisting path planning method and a crane, the hoisting path planning model construction method includes: building a crane model; constructing a hoisting system configuration space model based on a current operation scenario and the crane model, and the hoisting system configuration space model includes upper vehicle body data of a crane and lower vehicle body data of the crane; aiming at the hoisting system configuration space model and the upper vehicle body data, generating upper vehicle body raster graphic data of the crane; and aiming at the hoisting system configuration space model and the lower vehicle body data, generating lower vehicle body raster graphic data of the crane; and using an A-star algorithm and combining the upper vehicle body raster graphic data and the lower vehicle body raster graphic data to construct a hoisting path planning model; since the hoisting path planning model constructed is based on the upper vehicle body raster graphic data and the lower vehicle body raster graphic data, the entire path is divided into two groups: upper vehicle body and lower vehicle body, which effectively reducing the data volume during path search, and improving the efficiency of path planning.

### BRIEF DESCRIPTION OF THE DRAWINGS

In order to explain the present application or the technical solutions in the existing technology more clearly, the accompanying drawings needed to be used in the description of the embodiments or the existing technology will be briefly introduced below. Obviously, the accompanying drawings in the following description are only some embodiments of the present application, other accompanying drawings can be obtained based on these accompanying drawings without exerting creative efforts for those of ordinary skill in the art.

FIG. 1 is a schematic flow chart of a hoisting path planning model construction method provided by the present application.

FIG. 2 is a structural schematic view of a raster graphic provided by the present application.

FIG. 3 is a schematic flow chart of a hoisting path planning method provided by the present application.

FIG. 4 is a structural schematic view of a hoisting path planning model construction device provided by the present application.

FIG. 5 is a structural schematic view of a hoisting path planning device provided by the present application.

FIG. 6 is a structural schematic view of an electronic device provided by the present application.

### DETAILED DESCRIPTION OF THE EMBODIMENTS

In order to make the purpose, technical solutions and advantages of the present application clearer, the technical solutions in the present application will be clearly and completely described below in conjunction with the accompanying drawings in the present application. Obviously, the described embodiments are only some of the embodiments of the present application, but not all of the embodiments. Based on the embodiments of the present application, all other embodiments obtained by those of ordinary skill in the art without any creative work fall within the scope of the present application.

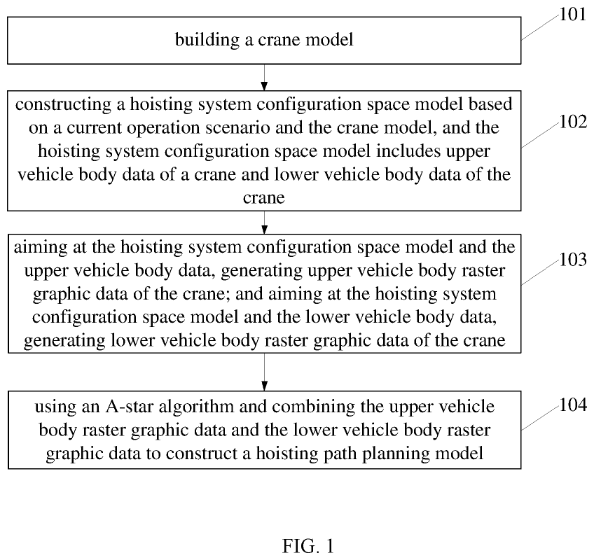

The hoisting path planning model construction method, the hoisting path planning method and the crane according to the present application will be described below combined with FIG. 1 to FIG. 6.

FIG. 1 is a schematic flow chart of a hoisting path planning model construction method provided by the present application.

As shown in FIG. 1, the embodiment according to the present application provides a hoisting path planning model construction method, the execution subject may be a remote control system, and specifically includes the following steps:

101. Building a crane model.

Hoisting refers to a general term for the installation and positioning of equipment by cranes, using various cranes to hoist equipment, workpieces, appliances, materials or the like during the inspection process or maintenance process to change its position.

Specifically, firstly establishing a crane model, that is, simulating the crane and expressing the crane in digital form, which can be understood that the crane is placed in the coordinate system, and each component structure of the crane corresponds to different coordinates. Simulating the crane in the database to establish the crane model. For cranes of different specifications, due to their own parameters are different, the crane model established is also different.

102. Constructing a hoisting system configuration space model based on a current operation scenario and the crane model, and the hoisting system configuration space model includes upper vehicle body data of a crane and lower vehicle body data of the crane.

Determining the current operation scenario of the crane, the current operation scenario refers to the area where the crane will operate, for example, if the crane is at a construction site, the construction site can be configured as the current operation scenario. Then, placing the crane model in the current operation scenario, constructing a hoisting system configuration space model, the hoisting system configuration space model can be a multi-dimensional system model. The expression of hoisting system configuration space model can be shown as (1):

T=(C(p,d),U(α,β,L)) (1)

Among them, C represents the lower vehicle body data of the crane, U represents the upper vehicle body data of the crane, p represents the Cartesian coordinates of the crane, d represents the direction vector of the crane, and a represents the main arm luffing angle, β represents the upper vehicle body rotation angle, L represents the hook lifting length, the boom length data is ignored here, the length of the boom can be known in advance, for example, the truss boom, based on the known each boom sections, the length of the boom can be calculated through simple addition and subtraction, and the telescopic boom can be pre-measured by the length sensor installed on the boom.

When the crane state is determined, that is, when the crane position remains unchanged and does not move, the mutual conversion of the crane configuration coordinates (α, β, L) to Cartesian coordinates (x, y, z) can be achieved.

As a whole, that is, various states of the crane are displayed in the hoisting system configuration space model, including walking parameters and steering parameters in the lower vehicle body data, and the main arm luffing angle, the upper vehicle body rotation angle and the hook lifting length in the upper vehicle body data, so that the hoisting system configuration space model can reflect the status information of the crane more comprehensively.

103. Aiming at the hoisting system configuration space model and the upper vehicle body data, generating upper vehicle body raster graphic data of the crane; and aiming at the hoisting system configuration space model and the lower vehicle body data, generating lower vehicle body raster graphic data of the crane.

Specifically, after constructing and obtaining the hoisting system configuration space model, the upper vehicle body data of the crane and lower vehicle body data of the crane need to be processed separately. According to the working characteristics of the crane, dividing actions of the crane into two combinations, one combination is the upper vehicle body actions including main arm luffing angle, upper vehicle body rotation angle and hook lifting length, another combination is the lower vehicle body actions including walking parameters and steering parameters, therefore, the data of the hoisting system configuration space model is divided into twice calculations, thereby reducing the difficulty of a single calculation, and also reducing the coupling degree.

When the crane is not moving, that is, under the premise that the walking parameters and steering parameters in the lower vehicle body data are determined, each U coordinate represents one configuration state of the crane, therefore, it is necessary to establish all the upper vehicle body raster graphic data of the upper vehicle body data. The upper vehicle body raster graphic data refers to the raster diagram composed of the main arm luffing angle, the upper vehicle body rotation angle and the hook lifting length. That is, the three degrees of freedom are the main arm luffing angle, the upper vehicle body rotation angle and the hook lifting length, each of which has several types of data of different sizes, and then arranging and combining them separately, thus the entire upper vehicle body raster graphic data can be formed.

When the crane moves, that is, when the walking parameters and/or steering parameters in the lower vehicle body data change, it is necessary to calculate the lower vehicle body raster graphic data of the crane. The way to generate the lower vehicle body raster graphic data is the same as the way to generate the upper vehicle body raster graphic data, and what the lower vehicle body raster graphic data represents is the data in the direction of two degrees of freedom.

104. Using an A-star algorithm and combining the upper vehicle body raster graphic data and the lower vehicle body raster graphic data to construct a hoisting path planning model.

Specifically, after obtaining the upper vehicle body raster graphic data and the lower vehicle body raster graphic data, the hoisting path planning model can be constructed. The upper vehicle body raster graphic data includes several nodes, and in the lower vehicle body raster graphic data also includes several nodes, and different nodes will then form several lines, that is, several hoisting paths.

Using the A-star algorithm to conduct optimization between the upper vehicle body raster graphic data and the lower vehicle body raster graphic data, combining the A-star algorithm with the upper vehicle body raster graphic data and the lower vehicle body raster graphic data, a hoisting path planning model is successfully constructed. The working principle of the hoisting path planning model is to obtain the upper vehicle body raster graphic data and the lower vehicle body raster graphic data in the current operation scenario, then use the A-star algorithm to perform a traversal search in the upper vehicle body raster graphic data and lower vehicle body raster graphic data to obtain the target path. The usage of the A-star algorithm to plan the path has the advantages of global optimality and good continuity, and can effectively streamline the configuration data volume, thereby reducing computational complexity.

A hoisting path planning model construction method provided by this embodiment, including: building a crane model; constructing a hoisting system configuration space model based on a current operation scenario and the crane model, and the hoisting system configuration space model includes upper vehicle body data of a crane and lower vehicle body data of the crane; aiming at the hoisting system configuration space model and the upper vehicle body data, generating upper vehicle body raster graphic data of the crane; and aiming at the hoisting system configuration space model and the lower vehicle body data, generating lower vehicle body raster graphic data of the crane; and using an A-star algorithm and combining the upper vehicle body raster graphic data and the lower vehicle body raster graphic data to construct a hoisting path planning model. Since the hoisting path planning model constructed is based on the upper vehicle body raster graphic data and the lower vehicle body raster graphic data, the entire path is divided into two groups: upper vehicle body and lower vehicle body, which effectively reducing the data volume during path search, and improving the efficiency of path planning.

Furthermore, based on the above embodiment, the upper vehicle body data in this embodiment includes: a main arm luffing angle, an upper vehicle body rotation angle and a hook lifting length; correspondingly, the aiming at the hoisting system configuration space model and the upper vehicle body data, generating the upper vehicle body raster graphic data of the crane includes: determining the hook lifting length; dividing the hook lifting length into a preset number of lifting intervals; aiming at an endpoint of each lifting intervals, performing a traversal search within the hoisting system configuration space model based on the main arm luffing angle and the upper vehicle body rotation angle, calculating upper vehicle body collision information, and generating the upper vehicle body raster graphic data of the crane.

Specifically, in the upper vehicle body data of the crane, there are three actions: the main arm luffing angle, the upper vehicle body rotation angle and the hook lifting length, the relationship among the three actions is: when the crane is working, the action of the hook lifting length is often the action performed at the beginning of the hoisting process and the end of the hoisting process, and the main arm luffing angle and the upper vehicle body rotation angle are the action of intermediate process. Therefore, in order to further improve the speed of path search, the hook lifting length L can be chosen as a control parameter to obtain the upper vehicle body raster graphic data.

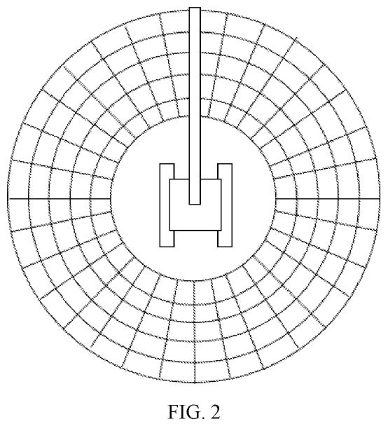

Dividing the hook lifting length into a preset number of lifting intervals, and then obtaining the endpoint of each lifting intervals, that is, L={L0, L1, L2, L3, L4 . . . Lm}, the corresponding intervals are [L0, L1], [L1, L2], [L2, L3] . . . [Lm−1, Lm]. Then, performing a traversal search based on the main arm luffing angle α and the upper vehicle body rotation angle β, (α, β)={(α0, β0), (α0, β1), (α0, β2) (α1, β0), (α1, β1), (α1, β2) (αn, βq)}, calculating the upper vehicle body collision information, and generating a set of corresponding raster graphic data for each L endpoint data. FIG. 2 is a structural schematic view of a raster graphic provided by the present application. As shown in FIG. 2, it is a schematic view of a raster graphic, in which the radial direction is related to the main arm luffing angle, the rotation angle is the upper vehicle body rotation angle, so each grid of each set of the raster graphic data includes collision information, edge information, load information and so on, each set hook lifting length L corresponds to a set of such data, and there are a total of m sets of the corresponding raster graphic data. All the m sets of the raster graphic data constitute the upper vehicle body raster graphic data of the entire crane. By performing path planning on the m sets of the raster graphic data, n valid paths can be obtained (referring to n types of paths from the starting point to the end point), comparing the n valid paths and selecting the optimal path as the current result path.

Furthermore, based on the above embodiment, the lower vehicle body data in this embodiment includes walking parameters and steering parameters; correspondingly, the aiming at the hoisting system configuration space model and the lower vehicle body data, generating the lower vehicle body raster graphic data of the crane includes: scanning and traversing within the hoisting system configuration space model based on the walking parameters and the steering parameters to obtain lower vehicle body collision information; and generating the lower vehicle body raster graphic data of the crane according to the lower vehicle body collision information.

Specifically, the above embodiment specifically explains the method of generating the upper vehicle body raster graphic data of a crane. Therefore, when the crane moves, it is necessary to firstly obtain the collision result of the upper vehicle body data firstly, then calculating the collision result of the lower vehicle body data, and combining upper vehicle body collision results and lower vehicle body collision results to get the final collision result. Its practical significance means that the crane ensures that the entire hoisting system does not collide during the walking of lower vehicle body, the turning of lower vehicle body, the luffing of upper vehicle body, the turning of upper vehicle body, and the hook lifting of upper vehicle body.

The process of generating the lower vehicle body raster graphic data is, firstly, scanning and traversing within the hoisting system configuration space model based on the walking parameters and the steering parameters to obtain lower vehicle body collision information, then, generating the lower vehicle body raster graphic data according to the lower vehicle body collision information. The lower vehicle body raster graphic data refers to the one-to-one corresponding relationship between the walking parameters of the crane and the steering parameters of the crane, the lower vehicle body raster graphic data can reflect all the corresponding steering parameters under the conditions of walking parameters, for the same reason, it can also reflect the corresponding walking parameters under all steering parameters conditions.

Furthermore, based on the above embodiment, in this embodiment, the using the A-star algorithm and combining the upper vehicle body raster graphic data and the lower vehicle body raster graphic data to construct the hoisting path planning model may include: using the A-star algorithm, performing a path planning on the upper vehicle body raster graphic data and the lower vehicle body raster graphic data respectively to obtain an upper vehicle body path planning model and a lower vehicle body path planning model; and combining the upper vehicle body path planning model and the lower vehicle body path planning model, and constructing the hoisting path planning model.

Specifically, the A-star algorithm is also called the A* search algorithm. The characteristic of A-star algorithm is introducing global information when checking every possible node in the shortest path, estimating the distance between the current node and the end point, and using it as a measure that evaluating the possibility of the node being on the shortest route. Therefore, in this embodiment, using the A-star algorithm can better complete the planning of path.

In order to reduce the amount of data processing as much as possible and increase the speed of data processing during the path planning process, performing path planning on the upper vehicle body raster graphic data and the lower vehicle body raster graphic data respectively, by grouping processing, the difficulty of a single calculation can be reduced and coupling degree is reduced. By dividing the hoisting path planning model into the upper vehicle body path planning model and the lower vehicle body path planning model, it can also enable the upper vehicle body path planning to be completed more quickly when the lower vehicle body is not moving, and performing path planning by the A-star algorithm, and global optimization can be achieved.

Furthermore, on the basis of the above embodiments, in this embodiment, establishing the crane model may include: obtaining the structural data of the crane, the structural data includes size information, motion parameters and load parameters; and establishing a crane mode based on the size information, the motion parameters and the load parameters.

Specifically, the way to obtain the structural data of the crane can be to directly read the product manual of the crane, or to manually input key data, or measure different data through various sensors, as long as the structural data of the crane can be accurately obtained. After accurately obtaining the size information, motion parameters and load parameters of the crane, converting the size information, motion parameters and load parameters into a spatial model, that is, the crane structure is simulated by means of lines. By accurately obtaining the size information, motion parameters and load parameters, the accuracy of the simulated crane can also be ensured, thereby improving the accuracy of the hoisting path planning model.

Based on the same general inventive concept, the present application also protects a hoisting path planning method.

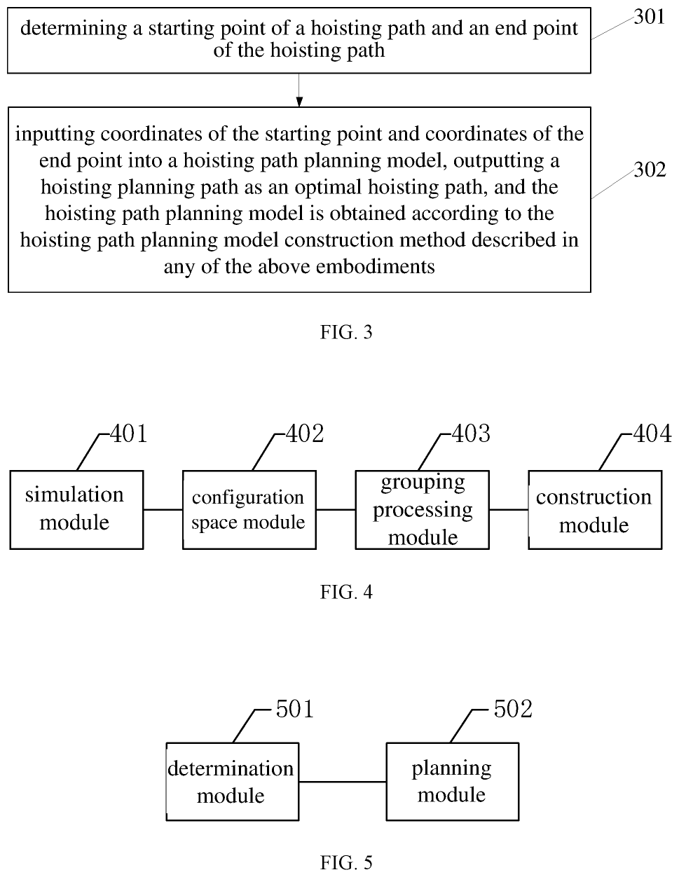

FIG. 3 is a schematic flow chart of a hoisting path planning method provided by the present application.

As shown in FIG. 3, the hoisting path planning method provided by this embodiment, its executive body can be a vehicle-mounted controller or a remote control terminal, and mainly includes the following steps:

301. Determining a starting point of a hoisting path and an end point of the hoisting path.

Specifically, when performing path planning, firstly, determining a starting point of the crane's work and an end point of the crane's work, that is, a starting point of a hoisting path and an end point of the hoisting path. Generally, the starting point of the hoisting is determined, or can be obtained directly from the positioning system. Therefore, in the specific implementation process, there is no need to enter the starting point data, and the end point data can be directly input, that is, only the end point of the hoisting path need to be determined. The way to determine the end point of the hoisting can be to directly read the end point data input by the user, or automatically locate the position of the end point after the user specifies the location, as long as the starting point of the hoisting path and the end point of the hoisting path can be effectively obtained.

302. Inputting coordinates of the starting point and coordinates of the end point into a hoisting path planning model, and outputting a hoisting planning path as an optimal hoisting path, and the hoisting path planning model is obtained according to the hoisting path planning model construction method of any of the above embodiments.

Specifically, after obtaining the starting point of the hoisting path and the end point of the hoisting path, the starting point data and the end point data can be input into the hoisting path planning model, the hoisting path planning model will perform path planning calculation based on the starting point and the end point, and output the hoisting planning path.

The process of planning the hoisting path between the starting point and the end point by the hoisting path planning model can be understood as, the hoisting path planning model first plans the upper vehicle body path, then plans the lower vehicle body path, and then combines the upper vehicle body path with the lower vehicle body path, and finally gets the hoisting planning path. By planning the upper vehicle body path and the lower vehicle body path in groups, the amount of data processing can be effectively reduced and the data processing speed can be improved. Hoisting path planning refers to choosing the most appropriate implementation path between the starting point and the end point, the hoisting system configuration space model constructed within the current operation scenario can be understood as a crisscross grid. By the A-star algorithm, it can quickly complete the traversal of each grid node, search for the most suitable path and complete the hoisting path planning, such as the final hoisting path planning, is the path with the shortest hoisting time. As the data volume increases, the operation efficiency of the A-star algorithm will decrease.

It should be noted that when the same crane performs the hoisting path planning within the same operation scenario, only need to obtain the starting point of the hoisting path and end point of the hoisting path. When the crane changes, or the operation scenario changes, the hoisting system configuration space model needs to be rebuilt to rebuild the hoisting path planning model to ensure the accuracy of path planning.

Furthermore, based on the above embodiment, after the outputting the hoisting planning path, it may also include: aiming at the upper vehicle body raster graphic data and the lower vehicle body raster graphic data respectively, and starting to search for an upper vehicle body raster graphic data node and a lower vehicle body raster graphic data node from the starting point; aiming at each of the upper vehicle body raster graphic data node and the lower vehicle body raster graphic data node, and determining a departed cost and a predicted cost; and marking the departed cost and the predicted cost in an open list, searching for a node with a smallest total cost in the open list, and using the node with the smallest total cost as a new starting point to start search until the end point is reached.

Specifically, after completing the hoisting path planning, the hoisting path output by the hoisting path planning model still needs to be calibrated and corrected. The correction method can be to separately calibrate the upper vehicle body path and lower vehicle body path, respectively aiming at the upper vehicle body raster graphic data and the lower vehicle body raster graphic data, searching around from the starting point, determining each upper vehicle body raster graphic data node and each lower vehicle body raster graphic data node, then, aiming at each upper vehicle body raster graphic data node and each lower vehicle body raster graphic data node, determining the departed cost and the predicted cost, and putting the departed cost and predicted cost in the open list, the open list refers to the nodes that have been searched. Then, searching for the node with the smallest total cost in the open list, and using the node with the smallest total cost as a new starting point to start search, repeating the search operation until the end point is reached, then, finding the optimal path from the open list as the final hoisting planning path, thus completing the optimization and calibration of the hoisting planning path.

Furthermore, on the basis of the above embodiment, in this embodiment, after outputting the hoisting planning path, may further including: converting the hoisting planning path into an action sequence of the crane based on the hoisting system configuration space model; and generating a crane control instruction based on the action sequence.

Specifically, after determining the hoisting planning path, it is necessary to convert its hoisting planning path into the action sequence of the crane, and generate the crane control instructions based on the action sequence, thereby controlling the crane to move according to the determined hoisting planning path. The control instruction of the crane controls each part of the crane to move according to the hoisting planning path, finally completes the control from the starting point of the hoisting to the end point of the hoisting, and the crane completes the hoisting operations. Due to the rationality of the hoisting path planning, the efficiency of the hoisting operations can be effectively improved.

In the present application, by decoupling the crane actions, it is flexibly applicable to different working modes of the crane, and the calculation efficiency of the path planning module is improved. Moreover, the hierarchical processing of upper vehicle body and lower vehicle body can achieve configuration space dimensionality reduction, reducing the data volume, standardizing the configuration coordinate parameters of the crane, and improving the performance of the path planning algorithm.

Based on the same general inventive concept, the present application also protects a hoisting path planning model construction device. The hoisting path planning model construction device provided by the present application will be described below. The hoisting path planning model construction device described below and the hoisting path planning model construction method described above can correspond to each other.

FIG. 4 is a structural schematic view of a hoisting path planning model construction device provided by the present application.

As shown in FIG. 4, an embodiment of the present application provides a hoisting path planning model construction device, including:

a simulation module 401 configured to build a crane model;

a configuration space module 402 configured to construct a hoisting system configuration space model based on a current operation scenario and the crane model, and the hoisting system configuration space model includes upper vehicle body data of a crane and lower vehicle body data of the crane;

a grouping processing module 403 configured to aim at the hoisting system configuration space model and the upper vehicle body data, generate upper vehicle body raster graphic data of the crane; and configured to aim at the hoisting system configuration space model and the lower vehicle body data, generate lower vehicle body raster graphic data of the crane; and

a construction module 404 configured to use an A-star algorithm and combine the upper vehicle body raster graphic data and the lower vehicle body raster graphic data to construct a hoisting path planning model.

This embodiment provides a hoisting path planning model construction device, including: building a crane model; constructing a hoisting system configuration space model based on a current operation scenario and the crane model, and the hoisting system configuration space model includes upper vehicle body data of a crane and lower vehicle body data of the crane; aiming at the hoisting system configuration space model and the upper vehicle body data, generating upper vehicle body raster graphic data of the crane; and aiming at the hoisting system configuration space model and the lower vehicle body data, generating lower vehicle body raster graphic data of the crane; and using an A-star algorithm and combining the upper vehicle body raster graphic data and the lower vehicle body raster graphic data to construct a hoisting path planning model. Since the hoisting path planning model constructed is based on the upper vehicle body raster graphic data and the lower vehicle body raster graphic data, the entire path is divided into two groups: upper vehicle body and lower vehicle body, which effectively reducing the data volume during path search, and improving the efficiency of path planning.

Furthermore, the upper vehicle body data in this embodiment includes: the main arm luffing angle, the upper vehicle body rotation angle, and the hook lifting length;

the grouping processing module 403 is specifically configured for:

determining the hook lifting length;

dividing the hook lifting length into a preset number of lifting intervals; and

aiming at an endpoint of each lifting intervals, performing a traversal search within the hoisting system configuration space model based on the main arm luffing angle and the upper vehicle body rotation angle, calculating upper vehicle body collision information, and generating the upper vehicle body raster graphic data of the crane.

Furthermore, the lower vehicle body data in this embodiment includes walking parameters and steering parameters;

the grouping processing module 403 is further specifically configured for:

scanning and traversing within the hoisting system configuration space model based on the walking parameters and the steering parameters to obtain lower vehicle body collision information; and

generating the lower vehicle body raster graphic data of the crane according to the lower vehicle body collision information.

Furthermore, the construction module 404 in this embodiment is specifically configured for:

using the A-star algorithm, performing a path planning on the upper vehicle body raster graphic data and the lower vehicle body raster graphic data respectively to obtain an upper vehicle body path planning model and a lower vehicle body path planning model; and

combining the upper vehicle body path planning model and the lower vehicle body path planning model, and constructing the hoisting path planning model.

Based on the same general inventive concept, the present application also protects a hoisting path planning device. The hoisting path planning device provided by the present application will be described below. The hoisting path planning device described below and the hoisting path planning method described above can correspond to each other.

FIG. 5 is a structural schematic view of a hoisting path planning device provided by the present application.

As shown in FIG. 5, the present application provides a hoisting path planning device, including:

a determination module 501 configured to determine a starting point of a hoisting path and an end point of the hoisting path; and

a planning module 502 configured to input the starting point and the end point into a hoisting path planning model and output a hoisting planning path as the optimal hoisting path, and the hoisting path planning model is obtained according to the hoisting path planning model construction method of any of the above embodiments.

Furthermore, based on the above embodiment, this embodiment also includes a correction module for:

aiming at the upper vehicle body raster graphic data and the lower vehicle body raster graphic data respectively, and starting to search for an upper vehicle body raster graphic data node and a lower vehicle body raster graphic data node from the starting point;

aiming at each of the upper vehicle body raster graphic data node and the lower vehicle body raster graphic data node, and determining a departed cost and a predicted cost; and

marking the departed cost and the predicted cost in an open list, searching for a node with a smallest total cost in the open list, and using the node with the smallest total cost as a new starting point to start search until the end point is reached.

Furthermore, based on the above embodiment, this embodiment also includes a conversion module for:

converting the hoisting planning path into an action sequence of the crane based on the hoisting system configuration space model; and

generating a crane control instruction based on the action sequence.

Based on the same general inventive concept, the present application also protects a crane, the crane is configured to execute the hoisting path planning method as in any of the above embodiments.

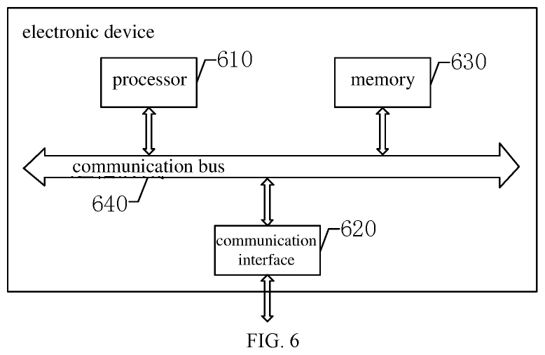

FIG. 6 is a structural schematic view of an electronic device provided by the present application.

As shown in FIG. 6, the electronic device may include: a processor 610, a communication interface 620, a memory 630, and a communication bus 640, the processor 610, the communication interface 620 and the memory 630 communicate with each other through the communication bus 640. The processor 610 can call logical instructions in the memory 630 to execute a hoisting path planning model construction method, the hoisting path planning model construction method includes building a crane model; constructing a hoisting system configuration space model based on a current operation scenario and the crane model, and the hoisting system configuration space model includes upper vehicle body data of a crane and lower vehicle body data of the crane; aiming at the hoisting system configuration space model and the upper vehicle body data, generating upper vehicle body raster graphic data of the crane; aiming at the hoisting system configuration space model and the lower vehicle body data, generating lower vehicle body raster graphic data of the crane; and using an A-star algorithm and combining the upper vehicle body raster graphic data and the lower vehicle body raster graphic data to construct a hoisting path planning model.

In addition, the above-mentioned logical instructions in the memory 630 can be implemented in the form of software functional units and can be stored in a computer-readable storage medium when sold or used as an independent product. Based on this understanding, the technical solution of the present application is essentially or the part that contributes to the existing technology or the part of the technical solution can be embodied in the form of a software product, the computer software product is stored in a storage medium and includes a number of instructions to cause a computer device (which may be a personal computer, a server, a network device or the like) to execute all steps or part of the steps of the methods described in various embodiments according to the present application. The aforementioned storage medium include: U disk, mobile hard disk, read-only memory (ROM), random access memory (RAM), magnetic disk or optical disk and other media that can store program code.

On the other hand, the present application also provides a computer program product, the computer program product includes a computer program, and the computer program can be stored on a non-transitory computer-readable storage medium. When the computer program is executed by the processor, the computer can execute the hoisting path planning model construction method provided by each of the above methods, the hoisting path planning model construction method includes building a crane model; constructing a hoisting system configuration space model based on a current operation scenario and the crane model, and the hoisting system configuration space model includes upper vehicle body data of a crane and lower vehicle body data of the crane; aiming at the hoisting system configuration space model and the upper vehicle body data, generating upper vehicle body raster graphic data of the crane; aiming at the hoisting system configuration space model and the lower vehicle body data, generating lower vehicle body raster graphic data of the crane; and using an A-star algorithm and combining the upper vehicle body raster graphic data and the lower vehicle body raster graphic data to construct a hoisting path planning model.

In another aspect, the present application also provides a non-transitory computer-readable storage medium on which a computer program is stored, the hoisting path planning model construction method provided by each of the above methods is implemented when the computer program is executed by a processor, the hoisting path planning model construction method includes building a crane model; constructing a hoisting system configuration space model based on a current operation scenario and the crane model, and the hoisting system configuration space model includes upper vehicle body data of a crane and lower vehicle body data of the crane; aiming at the hoisting system configuration space model and the upper vehicle body data, generating upper vehicle body raster graphic data of the crane; aiming at the hoisting system configuration space model and the lower vehicle body data, generating lower vehicle body raster graphic data of the crane; and using an A-star algorithm and combining the upper vehicle body raster graphic data and the lower vehicle body raster graphic data to construct a hoisting path planning model.

The device embodiments described above are only illustrative, in which the units described as separate components may or may not be physically separated, and the components shown as units may or may not be physical units, that is, it can be located in one place, or it can be distributed across multiple network units. Some or all of the modules can be selected according to actual needs to achieve the purpose of the solution of this embodiment. Persons of ordinary skill in the art can understand and implement without any creative effort.

Through the above description of the embodiments, those skilled in the art can clearly understand that each embodiment can be implemented by software plus a necessary general hardware platform, and certainly, it can also be implemented by hardware. Based on this understanding, the above technical solutions essentially or the part that contributes to the existing technology can be embodied in the form of software products, and the computer software product can be stored in a computer-readable storage medium, such as ROM/RAM, magnetic disk, optical disk and so on, including several instructions to cause a computer device (which can be a personal computer, server, network device or the like) to execute the methods described in various embodiments or certain parts of the embodiments.

Finally, it should be noted that the above embodiments are only configured to illustrate the technical solution of the present application, but not to limit it; although the present application has been described in detail with reference to the foregoing embodiments, those of ordinary skill in the art should understand that: it is still possible to modify the technical solutions recorded in the foregoing embodiments, or to make equivalent replacements for some of the technical features, and these modifications or substitutions does not make the essence of the corresponding technical solution deviate from the spirit and scope of the technical solutions of each embodiment according to the present application.

What is claimed is:

1. A hoisting path planning model construction method, comprising:
building a crane model;
constructing a hoisting system configuration space model based on a current operation scenario and the crane model, wherein the hoisting system configuration space model comprises upper vehicle body data of a crane and lower vehicle body data of the crane;
aiming at the hoisting system configuration space model and the upper vehicle body data, generating upper vehicle body raster graphic data of the crane; aiming at the hoisting system configuration space model and the lower vehicle body data, generating lower vehicle body raster graphic data of the crane; and
using an A-star algorithm and combining the upper vehicle body raster graphic data and the lower vehicle body raster graphic data to construct a hoisting path planning model.

2. The hoisting path planning model construction method according to claim 1, wherein the upper vehicle body data comprises: a main arm luffing angle, an upper vehicle body rotation angle and a hook lifting length;
the aiming at the hoisting system configuration space model and the upper vehicle body data, generating the upper vehicle body raster graphic data of the crane comprises:
determining the hook lifting length;
dividing the hook lifting length into a preset number of lifting intervals; and
aiming at an endpoint of each lifting intervals, performing a traversal search within the hoisting system configuration space model based on the main arm luffing angle and the upper vehicle body rotation angle, calculating upper vehicle body collision information, and generating the upper vehicle body raster graphic data of the crane.

3. The hoisting path planning model construction method according to claim 1, wherein the lower vehicle body data comprises walking parameters and steering parameters;
the aiming at the hoisting system configuration space model and the lower vehicle body data, generating the lower vehicle body raster graphic data of the crane comprises:
scanning and traversing within the hoisting system configuration space model based on the walking parameters and the steering parameters to obtain lower vehicle body collision information; and
generating the lower vehicle body raster graphic data of the crane according to the lower vehicle body collision information.

4. The hoisting path planning model construction method according to claim 1, wherein the using the A-star algorithm and combining the upper vehicle body raster graphic data and the lower vehicle body raster graphic data to construct the hoisting path planning model comprises:
using the A-star algorithm, performing a path planning on the upper vehicle body raster graphic data and the lower vehicle body raster graphic data respectively to obtain an upper vehicle body path planning model and a lower vehicle body path planning model; and
combining the upper vehicle body path planning model and the lower vehicle body path planning model, and constructing the hoisting path planning model.

5. A hoisting path planning method, comprising:
determining a starting point of a hoisting path and an end point of the hoisting path; and
inputting coordinates of the starting point and coordinates of the end point into a hoisting path planning model, outputting a hoisting planning path as an optimal hoisting path, and the hoisting path planning model is obtained according to the hoisting path planning model construction method according to claim 1.

6. The hoisting path planning method according to claim 5, after the outputting the hoisting planning path, further comprising:
aiming at the upper vehicle body raster graphic data and the lower vehicle body raster graphic data respectively, and starting to search for an upper vehicle body raster graphic data node and a lower vehicle body raster graphic data node from the starting point;
aiming at each of the upper vehicle body raster graphic data node and the lower vehicle body raster graphic data node, and determining a departed cost and a predicted cost; and
marking the departed cost and the predicted cost in an open list, searching for a node with a smallest total cost in the open list, and using the node with the smallest total cost as a new starting point to start search until the end point is reached.

7. The hoisting path planning method according to claim 5, after the outputting the hoisting planning path, further comprising:
converting the hoisting planning path into an action sequence of the crane based on the hoisting system configuration space model; and
generating a crane control instruction based on the action sequence.

8. A hoisting path planning model construction device, comprising:
a simulation module configured to build a crane model;
a configuration space module configured to construct a hoisting system configuration space model based on a current operation scenario and the crane model, and the hoisting system configuration space model comprises upper vehicle body data of a crane and lower vehicle body data of the crane;
a grouping processing module configured to aim at the hoisting system configuration space model and the upper vehicle body data, generate upper vehicle body raster graphic data of the crane; and configured to aim at the hoisting system configuration space model and the lower vehicle body data, generate lower vehicle body raster graphic data of the crane; and
a construction module configured to use an A-star algorithm and combine the upper vehicle body raster graphic data and the lower vehicle body raster graphic data to construct a hoisting path planning model.

9. A hoisting path planning device, comprising:
a determination module configured to determine a starting point of a hoisting path and an end point of the hoisting path; and
a planning module configured to input the starting point and the end point into a hoisting path planning model and output a hoisting planning path, wherein the hoisting path planning model is obtained according to the hoisting path planning model construction method according to claim 1.

10. A crane, wherein the crane is configured to execute the hoisting path planning method according to claim 5.
